(19) United States
(12) Patent Application Publication
(10) Pub. No.: US 2026/0074113 A1
(43) Pub. Date: Mar. 12, 2026

(54) LAYERED STRUCTURE OF TiO2 THIN FILM HAVING RUTILE CRYSTAL STRUCTURE AND METHOD FOR FORMING TiO2 THIN FILM HAVING RUTILE CRYSTAL STRUCTURE AND METHOD FOR MANUFACTURING CAPACITOR USING THE SAME

(71) Applicant: KOREA INSTITUTE OF SCIENCE AND TECHNOLOGY, Seoul (KR)

(72) Inventors: Jihoon JEON, Seoul (KR); Sunghoon HUR, Seoul (KR); Ji-Soo JANG, Seoul (KR); Hyun-Cheol SONG, Seoul (KR); Seung Hyub BAEK, Seoul (KR); Chong Yun KANG, Seoul (KR); Ji-Won CHOI, Seoul (KR); Jin Sang KIM, Seoul (KR); Seong Keun KIM, Seoul (KR)

(21) Appl. No.: 19/312,123

(22) Filed: Aug. 27, 2025

(30) Foreign Application Priority Data
Sep. 6, 2024 (KR) 10-2024-0121276

(51) Int. Cl. H01G 4/12; C23C 16/01; C23C 16/40; C23C 16/455; H01G 4/008; H01G 4/33

(52) U.S. Cl. CPC H01G 4/1218; C23C 16/01; C23C 16/405; C23C 16/45525; H01G 4/008; H01G 4/33

(57) ABSTRACT

The present invention relates to a layered structure of a TiO₂ thin film having a rutile crystal structure, a method for forming a TiO₂ thin film having a rutile crystal structure, and a method for manufacturing a capacitor using the same, which are capable of achieving both deposition of rutile TiO₂ at a temperature of 400° C. or less and miniaturization of a device by depositing rutile TiO₂ using a material having structural consistency with rutile TiO₂, while preventing a material having structural consistency with rutile TiO₂ from remaining between a substrate and rutile TiO₂.

### CROSS REFERENCE TO RELATED APPLICATION

The present application claims priority to Korean Patent Application No. 10-2024-0121276, filed on Sep. 6, 2024, the entire contents of which are hereby incorporated by this reference.

### BACKGROUND OF THE INVENTION

### Field of the Invention

The present invention relates to a layered structure of a TiO₂ thin film having a rutile crystal structure, a method for forming a TiO₂ thin film having a rutile crystal structure, and a method for manufacturing a capacitor using the same, and more specifically, to a layered structure of a TiO₂ thin film having a rutile crystal structure, a method for forming a TiO₂ thin film having a rutile crystal structure, and a method for manufacturing a capacitor using the same, in which a material having structural consistency with rutile TiO₂ is used to deposit rutile TiO₂, and the deposition of rutile TiO₂ and miniaturization of a device at a temperature of 400° C. or less may both be achieved by preventing the material having structural consistency with rutile TiO₂ from remaining between a substrate and rutile TiO₂.

### DESCRIPTION OF GOVERNMENT-SPONSORED RESEARCH

This invention was carried out with the support of Ministry of Trade, Industry and Energy under a research project of Unique Project identification number: 2410000279 and Project identification number: 00234833 titled “Interface analysis and engineering of high-k dielectrics/electrodes for sub-10 nm DRAM capacitors implementation”, as part of the research project of “Public-private joint investment in training advanced semiconductor personnel (R&D)” managed by Korea Planning&Evaluation Institute of Industrial Technology (KEIT) from Jan. 1, 2024 to Dec. 31, 2024.

This invention was carried out with the support of Ministry of Science and ICT under a research project of Unique Project identification number: 2710035749 and Project identification number: CAP22033-000 titled “Ultra low power, high density, and high bandwidth DRAM based on monolithic 3D integration of oxide semiconductor thin-film transistor”, as part of the research project of “Support for research operation expenses of the National Research Council of Science & Technology (major project expenses)” managed by National Research Council of Science & Technology (NST) from Jun. 1, 2024 to May 31, 2025.

### Description of the Related Art

The TiO₂ having a rutile crystal structure (hereinafter, referred to as rutile TiO₂) is a material expected to be applied as a dielectric film of a DRAM capacitor because of having a high dielectric constant of 80 or more. For reference, the TiO₂ having an anatase crystal structure has a dielectric constant of about 40.

In order to apply rutile TiO₂ as the dielectric film of a DRAM capacitor, the miniaturization of a device and the process temperature need to be satisfied. That is, since the process limit temperature of a DRAM device is 500° C. or less, the deposition temperature of rutile TiO₂ needs to also be 500° C. or less, and, for the miniaturization of a device, a requirement that the thickness of the capacitor be minimized needs to be satisfied.

However, in general, rutile TiO₂ is known to be formed at a temperature of 600° C. or more. For example, in a case of forming rutile TiO₂ using an atomic layer deposition (ALD) process, a temperature of 600° C. or more is required, and in a case of forming rutile TiO₂ through heat treatment, a temperature of 700° C. or more is required. Patent Document 1 (Korean Patent Publication No. 2024-0075486) discloses a technology of converting titanium oxide into a rutile phase through heat treatment at 400 to 700° C.

In order to solve such a high-temperature deposition problem of rutile TiO₂, a technology of growing rutile TiO₂ on a thin film layer having structural consistency with rutile TiO₂ has been proposed, and through this method, the formation of rutile TiO₂ at a temperature of 400° C. or less becomes possible. Here, the thin film layer having structural consistency with rutile TiO₂ means a metal such as Ru, Ir, or the like or a metal oxide having a rutile crystal structure such as TiO₂, SnO₂, RuO₂, IrO₂, MoO₂, VO₂, or the like.

Through such a method, the requirement of 500° C. or less, which is the process limit temperature of DRAM, may be satisfied, however, this method has a problem in that the thickness of the capacitor increases due to the essential requirement of the thin film layer having structural consistency with rutile TiO₂. Patent Document 2 (Korean Registered Patent No. 1892632) discloses a technology of configuring an upper electrode or a lower electrode of a capacitor with a compound of RuO₂ and SnO₂ having structural consistency with rutile TiO₂, and Patent Document 3 (Korean Registered Patent No. 717768) discloses a technology of forming a second dielectric film composed of rutile TiO₂ on a first dielectric film of TiO₂. In addition, Patent Documents 4 and 5 also disclose technologies of forming rutile TiO₂ using a material having structural consistency with rutile TiO₂.

### SUMMARY OF THE INVENTION

The present invention has been devised in order to solve the above-described problems, and has an object to provide a layered structure of a TiO₂ thin film having a rutile crystal structure, a method for forming a TiO₂ thin film having a rutile crystal structure, and a method for manufacturing a capacitor using the same, in which rutile TiO₂ is deposited using a material having structural consistency with rutile TiO₂, and the deposition of rutile TiO₂ at a temperature of 400° C. or less and the miniaturization of a device may both be achieved by preventing the material having structural consistency with rutile TiO₂ from remaining between a substrate and rutile TiO₂.

To achieve the aforementioned object, there is provided a layered structure of a TiO₂ thin film having a rutile crystal structure, according to the present invention. The layered structure may comprise: a substrate; and a rutile TiO₂ thin film laminated on the substrate, wherein a crystal structure of the substrate and a crystal structure of the rutile TiO₂ thin film are different from each other, and the rutile TiO₂ thin film is formed by an atomic layer deposition (ALD) process at 400° C. or less.

The substrate may be one of a semiconductor substrate, a conductive substrate, or an insulating substrate.

The substrate may be a lower electrode of a capacitor or have a structure in which an insulating layer is provided on the lower electrode. In addition, the lower electrode of the capacitor may be made of one of TiN, TiAlN, Si, NbN, TaN, or MoN, and the insulating layer may be made of one of ZrO₂, HfO₂, Al₂O₃, LaOₓ, TaOₓ, or NbO₂.

An upper electrode of the capacitor may be further provided on the rutile TiO₂ thin film.

There is provided a method for forming a TiO₂ thin film having a rutile crystal structure, according to the present invention. The method may comprise: a first step of laminating an ultra-thin film sacrificial layer on a substrate; and a second step of depositing a rutile TiO₂ thin film on the substrate through an atomic layer deposition (ALD) process, in which, in the second step, a reaction in which the rutile TiO₂ thin film is formed on the ultra-thin film sacrificial layer in the form of a metal oxide having structural consistency with rutile TiO₂, and a reaction in which the ultra-thin film sacrificial layer in the form of the metal oxide reacts with an oxidizing agent to be converted into a volatile oxide and removed, may be carried out.

The ultra-thin film sacrificial layer may be capable of existing as a metal oxide having structural consistency with rutile TiO₂ and be capable of being converted into a volatile oxide, which is a gaseous material, when reacting with an oxidizing agent.

Crystal structures of the substrate and the rutile TiO₂ thin film may be different from each other.

The ultra-thin film sacrificial layer may be made of a metal or a metal oxide.

The metal may be one of Ru, Ir, Mo, V, Sn, or Nb, and the metal oxide may be one of RuO₂, IrO₂, MoO₂, VO₂, SnO₂, or NbO₂.

When the ultra-thin film sacrificial layer is made of a metal, in the second step, a process in which the metal reacts with an oxidizing agent to be converted into a metal oxide having structural consistency with rutile TiO₂, a process in which the rutile TiO₂ thin film is formed on the metal oxide having structural consistency with rutile TiO₂, and a process in which the metal oxide having structural consistency with rutile TiO₂ reacts with the oxidizing agent to be converted into a volatile oxide and removed, may be carried out.

When the ultra-thin film sacrificial layer is made of a metal oxide, in the second step, a process in which the rutile TiO₂ thin film is formed on the metal oxide having structural consistency with rutile TiO₂, and a process in which the metal oxide having structural consistency with rutile TiO₂ reacts with an oxidizing agent to be converted into a volatile oxide and removed, may be carried out.

The substrate may be one of a semiconductor substrate, a conductive substrate, or an insulating substrate.

The substrate may be a lower electrode of a capacitor or have a structure in which an insulating layer is provided on the lower electrode. The lower electrode of the capacitor may be made of one of TiN, TiAlN, Si, NbN, TaN, or MoN, and the insulating layer may be made of one of ZrO₂, HfO₂, Al₂O₃, LaOₓ, TaOₓ, or NbOₓ, or a composite film thereof.

The ultra-thin film sacrificial layer may have a thickness of 6 nm or less.

The atomic layer deposition (ALD) process of the second step may be carried out at a temperature of 400° C. or less.

The atomic layer deposition (ALD) process of the second step may comprise repeating a titanium precursor supply process and an oxidizing agent supply process, and the oxidizing agent may be supplied by the oxidizing agent supply process, and the oxidizing agent may be O₃ or O₃ plasma.

There is provided a method for manufacturing a capacitor, according to the present invention. The method may comprise: a first step of laminating an ultra-thin film sacrificial layer on a lower electrode structure; a second step of depositing a rutile TiO₂ thin film on the lower electrode structure through an atomic layer deposition (ALD) process; and a third step of laminating an upper electrode on the rutile TiO₂ thin film, in which, in the second step, a reaction in which the rutile TiO₂ thin film is formed on an ultra-thin film sacrificial layer in the form of a metal oxide having structural consistency with rutile TiO₂, and a reaction in which the ultra-thin film sacrificial layer in the form of a metal oxide reacts with an oxidizing agent to be converted into a volatile oxide and removed, may be carried out.

Crystal structures of the lower electrode structure and the rutile TiO₂ thin film may be different from each other, and the lower electrode structure may be composed of a lower electrode or have a structure in which a lower dielectric layer is provided on the lower electrode.

The lower electrode of the capacitor may be made of one of TiN, TiAlN, Si, NbN, TaN, or MoN, and the lower dielectric layer may be made of one of ZrO₂, HfO₂, Al₂O₃, LaOₓ, TaOₓ, or NbOₓ, or a composite film thereof.

According to the present invention, the layered structure of a TiO₂ thin film having a rutile crystal structure, the method for forming a TiO₂ thin film having a rutile crystal structure, and the method for manufacturing a capacitor using the same have the following effects.

A rutile TiO₂ having a high dielectric constant can be deposited through a low-temperature process of 400° C. on a substrate having no structural consistency with rutile TiO₂. Accordingly, in manufacturing a semiconductor device, for example, a DRAM capacitor, a lower electrode or a lower dielectric layer having structural consistency with rutile TiO₂ is not required, thereby enabling miniaturization of a device.

### BRIEF DESCRIPTION OF THE DRAWINGS

FIGS. 1A, 1B, 1C, and 1D are process schematic diagrams for explaining a method for forming a TiO₂ thin film having a rutile crystal structure according to one embodiment of the present invention.

FIG. 2 is an experimental result showing the removal characteristics of Ru according to the deposition thickness of an Ru metal layer and the supply time (exposure time) of O₃ in the initial TiO₂ thin film deposition cycle.

FIG. 3 is an XPS analysis result showing the presence or absence of residual Ru when the supply time of O₃ is applied as 3 seconds and 60 seconds, respectively, in a case where the deposition thickness of the Ru metal layer is 0.6 nm.

FIG. 4 is a result of GIXRD analysis of deposited TiO₂ in the cases where the Ru metal layer is applied with deposition thicknesses of 0.6 nm and 2.5 nm, respectively.

FIG. 5 shows a change in equivalent oxide film thickness according to the thickness of rutile TiO₂.

FIG. 6 is a GIXRD analysis result of TiO₂ formed according to Experimental Example 4.

FIG. 7 is an experimental result showing the dielectric characteristics of a capacitor manufactured according to Experimental Example 4.

### DETAILED DESCRIPTION OF THE INVENTION

The present invention presents a technology capable of implementing the miniaturization of a device along with the deposition of rutile TiO₂ through a low-temperature process of 400° C. or less.

As described in “Description of the Related Art” above, in order to apply rutile TiO₂ to semiconductor devices such as DRAM, and the like, a temperature condition of 500° C. or less needs to be satisfied and the miniaturization of a device needs to be possible, however, the conventional technologies, as disclosed in Patent Documents 1 to 5, have a problem in that rutile TiO₂ is deposited at high temperature or a material having structural consistency with rutile TiO₂ needs to be applied, thereby increasing the thickness of a device.

The present invention presents a structure in which rutile TiO₂ is laminated on a substrate.

In the present invention, during the deposition of TiO₂, TiO₂ is deposited on a material having structural consistency with rutile TiO₂ so that the crystal structure of the deposited TiO₂ has a rutile phase, and at a point in time when the deposition of rutile TiO₂ is completed, the material having structural consistency with rutile TiO₂ is all removed so that a structure in which rutile TiO₂ is laminated on a substrate is completed.

Through such a method, rutile TiO₂ may be deposited at a low temperature of 400° C. or less, and, in the final product, since there is no material having structural consistency with rutile TiO₂ between the substrate and rutile TiO₂, the miniaturization of a device becomes possible.

Such a process of the present invention uses the characteristic that metals such as Ru, Ir, and the like are converted into volatile oxides under specific conditions. In a state where an ultra-thin film sacrificial layer is laminated on a substrate, when TiO₂ deposition is performed through an atomic layer deposition (ALD) process on the ultra-thin film sacrificial layer, a structure in which rutile TiO₂ is laminated on a substrate is completed. In this case, the atomic layer deposition (ALD) process for the deposition of TiO₂ is performed at 400° C. or less.

The ultra-thin film sacrificial layer, as described above, has the characteristic of being converted into a volatile oxide under specific conditions, and in addition needs to have structural consistency with rutile TiO₂. That is, the ultra-thin film sacrificial layer needs to be capable of being converted into a volatile oxide under specific conditions and, at the same time, needs to have structural consistency with rutile TiO₂. The ultra-thin film sacrificial layer satisfying such conditions may be made of one of Ru, Ir, Mo, V, or Sn, or one of oxides thereof, which are RuO₂, IrO₂, MoO₂, VO₂, or SnO₂.

As such, the ultra-thin film sacrificial layer needs to have structural consistency with rutile TiO₂ for the formation of rutile TiO₂, and since it needs not to exist between the substrate and rutile TiO₂ after the formation of rutile TiO₂, it needs to have the characteristic of being converted into a volatile oxide.

The characteristic of being converted into a volatile oxide under specific conditions is described as follows.

As an example of an ultra-thin film sacrificial layer, in the case of Ru, Ru may be converted into RuO₂, RuO₃, or RuO₄ depending on the reaction result with an oxidizing agent containing oxygen (O). Among these, RuO₂ is a solid material, and RuO₃ and RuO₄ are gaseous materials as volatile oxides. Accordingly, when Ru or RuO₂ on a substrate is converted into RuO₃ or RuO₄, which are volatile oxides, there is no Ru-based material such as Ru, RuO₂, and the like, that is, the ultra-thin film sacrificial layer, on the substrate. Here, the oxidizing agent containing oxygen (O) may mean O₃ or O₂ plasma, and is supplied for the formation of TiO₂ during an atomic layer deposition (ALD) process.

The same principle applies to Ir. Ir may be converted into IrO₂ or IrO₃ depending on the reaction result with O₃ (or O₂plasma), and among these, IrO₂ is a solid material, and IrO₃ is a gaseous material as a volatile oxide. Accordingly, when Ir or IrO₂ on a substrate is converted into IrO₃, which is a volatile oxide, there is no Ir-based material such as Ir, IrO₂ , and the like on the substrate.

Through such a principle, a metal or a metal oxide on a substrate having the characteristic of being converted into a volatile oxide may be converted into a volatile oxide and removed by the reaction with O₃ or O₂ plasma.

The formation of TiO₂ through an atomic layer deposition (ALD) process is performed by repeating a titanium precursor supply process and an oxidizing agent supply process in a state where an ultra-thin film sacrificial layer is laminated on a substrate, and the oxidizing agent of the oxidizing agent supply process is O₃ or O₂ plasma as described above. Accordingly, along with the formation of TiO₂ by the supply of O₃ or O₂ plasma, the ultra-thin film sacrificial layer is removed. More precisely, after TiO₂ is formed by the supply of O₃ or O₂ plasma, the ultra-thin film sacrificial layer is removed by an additional supply of O₃ or O₂ plasma.

In the present invention, the TiO₂ formed by the atomic layer deposition (ALD) process needs to have a rutile crystal structure, and the TiO₂ on the ultra-thin film sacrificial layer is TiO₂ having a rutile crystal structure, that is, rutile TiO₂.

In order for rutile TiO₂ to be deposited by the atomic layer deposition (ALD) process, the ultra-thin film sacrificial layer needs to have structural consistency with rutile TiO₂. As the ultra-thin film sacrificial layer has structural consistency with rutile TiO₂, the TiO₂ deposited by the atomic layer deposition (ALD) process forms a rutile crystal structure. In the present invention, the material having structural consistency with rutile TiO₂ may mean a material having a rutile crystal structure.

Meanwhile, the fact that the ultra-thin film sacrificial layer has structural consistency with rutile TiO₂ means that the ultra-thin film sacrificial layer forms a metal oxide form having a rutile crystal structure. Accordingly, in a case where the ultra-thin film sacrificial layer is a metal, a state converted into a metal oxide form is achieved by the reaction with O₃ or O₂ plasma. For example, in a case where the ultra-thin film sacrificial layer is an Ru metal layer, it is converted into RuO₂ having structural consistency with rutile TiO₂ by the reaction with O₃ or O₂ plasma, and in a case where the ultra-thin film sacrificial layer is an Ir metal layer, a state converted into IrO₂ having structural consistency with rutile TiO₂ is achieved by the reaction with O₃ or O₂ plasma. On the other hand, in a case where the ultra-thin film sacrificial layer is laminated in a metal oxide form having structural consistency with rutile TiO₂, the above-described conversion process into a metal oxide is omitted.

Under such a technical background, the principle of forming rutile TiO₂ on a substrate is described as follows.

In a state where the ultra-thin film sacrificial layer is laminated on a substrate, TiO₂ deposition is performed through an atomic layer deposition (ALD) process. Here, the ultra-thin film sacrificial layer may be made of a metal or a metal oxide, and hereinafter, for convenience of explanation, a case where it is made of a metal will be mainly described. As described above, the ultra-thin film sacrificial layer has both the capability of being converted into a volatile oxide and structural consistency with rutile TiO₂ when converted into a solid metal oxide.

The deposition of TiO₂ through an atomic layer deposition (ALD) process is carried out with a combination of a titanium precursor supply process and an oxidizing agent supply process as one cycle, while a plurality of cycles are repeated. Accordingly, in a state where the ultra-thin film sacrificial layer is laminated on a substrate, a titanium precursor is adsorbed on the ultra-thin film sacrificial layer by the titanium precursor supply process, and then, the oxidizing agent of O₃ or O₂ plasma is supplied by the oxidizing agent supply process.

As the oxidizing agent, for example, O₃, is supplied by the oxidizing agent supply process, TiO₂ is formed by the reaction between the titanium precursor and O₃, and at the same time, a metal layer constituting the ultra-thin film sacrificial layer, for example, the Ru metal layer, forms RuO₂ by the reaction with O₃. As such, the formation of TiO₂ and the conversion of the ultra-thin film sacrificial layer into a metal oxide are carried out simultaneously by the supply of O₃. In this case, since the ultra-thin film sacrificial layer in the form of a metal oxide, for example, RuO₂, has structural consistency with rutile TiO₂, the TiO₂ formed on the ultra-thin film sacrificial layer is formed as TiO₂ having a rutile crystal structure.

That is, by the supply of O₃, the ultra-thin film sacrificial layer is converted into a metal oxide form having structural consistency with rutile TiO₂, and as the ultra-thin film sacrificial layer is converted into a metal oxide form having structural consistency with rutile TiO₂, the TiO₂ formed on the ultra-thin film sacrificial layer is deposited in the form of rutile TiO₂.

As such, along with the formation of rutile TiO₂ on the ultra-thin film sacrificial layer, when an oxidizing agent, for example, O₃, is supplied in excess, the ultra-thin film sacrificial layer in the form of a metal oxide is converted into a volatile oxide and removed. For example, RuO₂ is converted into a volatile oxide, RuO₃ or RuO₄, by the excessive supply of O₃, and removed. In the case of IrO₂, it is converted into IrO₃, which is a volatile oxide, and removed by the reaction with excessively supplied O₃.

As the ultra-thin film sacrificial layer in the form of a metal oxide is converted into a volatile oxide and removed by the reaction with the excessively supplied oxidizing agent, the form in which only rutile TiO₂ is laminated on the substrate is achieved.

As described above, the present invention can achieve the miniaturization of a device by using both the conversion characteristic of the ultra-thin film sacrificial layer into a metal oxide form having structural consistency with rutile TiO₂ and the characteristic of being converted into a volatile oxide by the reaction with an oxidizing agent, so that rutile TiO₂ is deposited through a low-temperature process of 400° C. or less and a material having structural consistency with rutile TiO₂ does not exist in the final product.

Hereinafter, with reference to the drawings, a layered structure of a TiO₂ thin film having a rutile crystal structure, a method for forming a TiO₂ thin film having a rutile crystal structure, and a method for manufacturing a capacitor using the same according to one embodiment of the present invention will be described in detail.

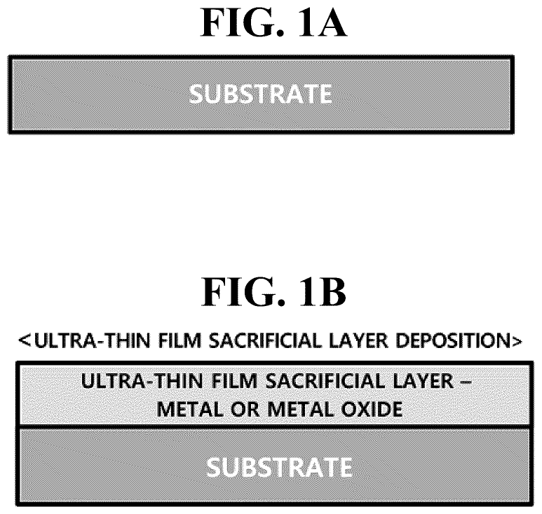

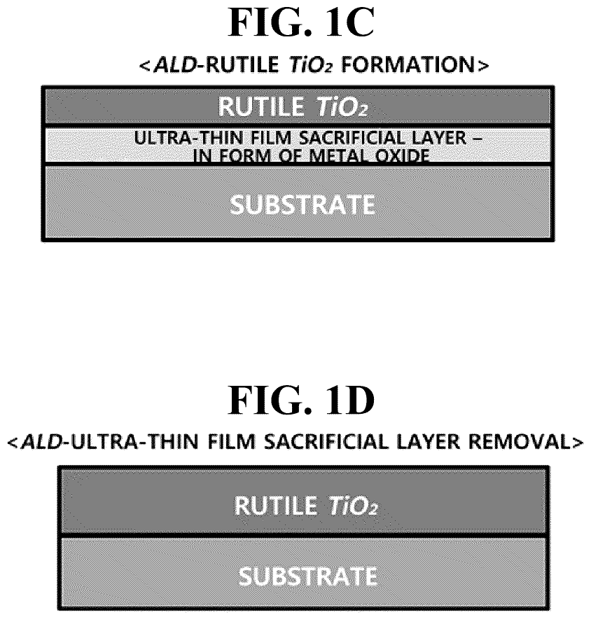

With reference to FIG. 1A to FIG. 1D, a substrate is prepared (see FIG. 1A). There is no particular limitation on the constituent material and role of the substrate. That is, a substrate having various uses or purposes may be prepared. In one embodiment, the substrate may mean a semiconductor substrate, a conductive substrate, or an insulating substrate, and so on. Here, the conductive substrate may mean an electrode of a semiconductor device, and the insulating substrate may mean an insulating layer of a semiconductor device. In a more specific embodiment, the conductive substrate may mean a lower electrode of a capacitor, and the insulating substrate may mean a structure in which an insulating layer is provided on the lower electrode of a capacitor. In addition, the lower electrode of a capacitor may be made of one of TiN, TiAlN, Si, NbN, TaN, or MoN in one embodiment, and the insulating layer may be made of one of ZrO₂, HfO₂, Al₂O₃, LaOₓ, TaOₓ, or NbOₓ, or a composite film thereof, in one embodiment.

In a state where the substrate is prepared, the ultra-thin film sacrificial layer is laminated on the substrate (see FIG. 1B).

The ultra-thin film sacrificial layer is made of a metal or a metal oxide, and the metal or metal oxide constituting the ultra-thin film sacrificial layer needs to satisfy two requirements. One is that it needs to have structural consistency with rutile TiO₂ in a metal oxide state, and the other is that it needs to be capable of being converted into a volatile oxide, which is a gaseous material, by the reaction with an oxidizing agent.

In a case where the ultra-thin film sacrificial layer is composed of a metal, it may be made of one of Ru, Ir, Mo, V, Sn, or Nb. In addition, in a case where the ultra-thin film sacrificial layer is composed of a metal oxide, it may be made of one of RuO₂, IrO₂, MoO₂, VO₂, SnO₂, or NbO₂.

The lamination of the ultra-thin film sacrificial layer may be performed by deposition using a conventional chemical vapor deposition (CVD), physical vapor deposition (PVD), or the like, and, in one embodiment, an atomic layer deposition (ALD) process may be used. However, the deposition temperature of the ultra-thin film sacrificial layer needs to be lower than the DRAM process temperature. For example, the ultra-thin film sacrificial layer needs to be deposited at a temperature of less than 500° C. Preferably, the ultra-thin film sacrificial layer is deposited at a temperature of 400° C. or less.

The thickness of the ultra-thin film sacrificial layer plays an important role in whether the present invention is implemented. Accordingly, the ultra-thin film sacrificial layer needs to be deposited to have a thickness of 6 nm or less, and preferably, to have a thickness of 3 nm or less. More preferably, it is deposited to have a thickness of 2.5 nm or less. When the thickness of the ultra-thin film sacrificial layer is thicker than the above reference, a problem occurs in that the ultra-thin film sacrificial layer remains in the final product.

Meanwhile, as the ultra-thin film sacrificial layer is laminated in an ultra-thin film form of 6 nm or less, the ultra-thin film sacrificial layer on the substrate may exist discontinuously.

In a state where the ultra-thin film sacrificial layer is laminated on the substrate, TiO₂ deposition is carried out through an atomic layer deposition (ALD) process.

The deposition of TiO₂ through the atomic layer deposition (ALD) process means that a titanium precursor supply process and an oxidizing agent supply process are repeated. That is, the combination of a titanium precursor supply process and an oxidizing agent supply process is defined as one cycle, and as such cycles are repeated multiple times, the deposition of TiO₂ is performed.

The titanium precursor supply process is carried out by the processes of supplying a titanium precursor to a reaction chamber in which the atomic layer deposition (ALD) process is carried out, adsorbing the titanium precursor onto the ultra-thin film sacrificial layer, and purging the unadsorbed titanium precursor with an inert gas. Various precursors may be used as the titanium precursor, and, in one embodiment, C₅(CH₃)₅Ti(OMe)₃ may be used.

The oxidizing agent supply process is a process of supplying an oxidizing agent, for example, O₃ or O₂ plasma, into the reaction chamber in a state where the titanium precursor is adsorbed on the ultra-thin film sacrificial layer, and TiO₂ is formed by the reaction between the titanium precursor and the oxidizing agent according to the oxidizing agent supply. After TiO₂ is formed, a process of purging reaction by-products such as ligands or the like and unreacted oxidizing agent by injecting an inert gas is carried out.

As such, TiO₂ is formed on the ultra-thin film sacrificial layer by the oxidizing agent supply process following the titanium precursor supply process, and in this process, a reaction in which the ultra-thin film sacrificial layer is converted into a metal oxide having structural consistency with rutile TiO₂, a reaction in which the TiO₂ deposited on the ultra-thin film sacrificial layer in the form of a metal oxide is deposited in the form of rutile TiO₂ (see FIG. 1C), and a reaction in which the ultra-thin film sacrificial layer in the form of a metal oxide is converted into a volatile oxide, which is a gaseous material, and removed (see FIG. 1D), are carried out together. These reactions may be performed in the above-described order in a time series manner or may not.

In a case where the ultra-thin film sacrificial layer is made of a metal layer, for example, in a case where the ultra-thin film sacrificial layer is made of an Ru metal layer, the Ru metal layer is converted into RuO₂ by the reaction with an oxidizing agent, for example, O₂, and since RuO₂ forms a rutile crystal structure having structural consistency with rutile TiO₂, the TiO₂ deposited on RuO₂ becomes rutile TiO₂. Accordingly, a structure in which RuO₂ and rutile TiO₂ are sequentially laminated on the substrate is formed, and in this state, when a predetermined amount of O₃ is further supplied, RuO₂ and unreacted Ru on the substrate are converted into RuO₃ and RuO₄, which are volatile oxides. Since RuO₃ and RuO₄ are gaseous materials, they are removed from the substrate immediately upon conversion. Accordingly, a structure in which rutile TiO₂ is laminated on the substrate is finally formed. Here, the rutile TiO₂ on the substrate may correspond to the dielectric layer of a capacitor.

On the other hand, in a case where the ultra-thin film sacrificial layer is laminated in the form of a metal oxide having structural consistency with rutile TiO₂, the above-described reaction of converting the metal layer into a metal oxide having structural consistency with rutile TiO₂ is omitted.

Through the above method, rutile TiO₂ may be formed on the substrate. Meanwhile, in a case where the substrate is a lower electrode structure of a capacitor including a lower electrode or a lower dielectric layer of the capacitor, the capacitor may be completed by forming an upper electrode on the rutile TiO₂ after the formation of rutile TiO₂. Here, the upper electrode is not particularly limited in its material and structure.

As described above, the layered structure of a TiO₂ thin film having a rutile crystal structure, the method for forming a TiO₂ thin film having a rutile crystal structure, and the method for manufacturing a capacitor using the same according to one embodiment of the present invention have been described. Hereinafter, the present invention will be described in more detail through experimental examples.

### Experimental Example 1: Removal Characteristics of Ultra-Thin Film Sacrificial Layer According to Deposition Thickness and Oxidizing Agent Supply Time

A Si substrate (n⁺⁺) on which 5 nm of Al₂O₃ was laminated was prepared, and an Ru metal layer was deposited on Al₂O₃ through an atomic layer deposition (ALD) process. In order to examine the removal characteristics according to the deposition thickness of the Ru metal layer, the Ru metal layer was deposited with thicknesses of 0.6 nm, 2.5 nm, 4.5 nm, and 6.1 nm, respectively. TiO₂ was deposited on the Ru metal layer through an atomic layer deposition (ALD) process. For the deposition of TiO₂, C₅(CH₃)₅Ti(OMe)₃ was supplied for 4 seconds, and N₂ gas was supplied for 15 seconds to perform purging. Then, O₃ was supplied for several seconds, and purging was performed for 10 seconds using N₂ gas. The above deposition cycle was repeatedly performed 20 times. In order to examine the removal characteristics according to the O₃ supply time, the O₃ supply time was applied differently as 3 seconds, 20 seconds, 60 seconds, and 180 seconds, respectively. In addition, the Ru metal layer was deposited at a temperature of 250° C., and TiO₂ was deposited at a temperature of 330° C. In addition, for comparison, TiO₂ was also deposited in a case where the Ru metal layer was not laminated.

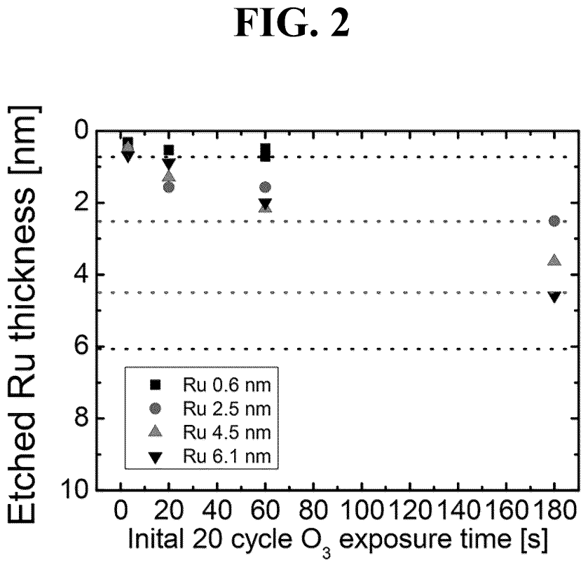

FIG. 2 is an experimental result showing the removal characteristics of Ru according to the deposition thickness of the Ru metal layer and the O₃ supply time, and in FIG. 2, the dotted line indicates the deposition thickness of the Ru metal layer.

With reference to FIG. 2, in the case where the deposition thickness of the Ru metal layer is 0.6 nm, it can be seen that Ru was completely removed when the O₃ supply time was 60 seconds, and in the case where the deposition thickness of the Ru metal layer is 2.5 nm, it can be confirmed that Ru was completely removed when the O₃ supply time was 180 seconds. On the other hand, in the case where the deposition thickness of the Ru metal layer is 4.5 nm or 6.1 nm, it can be seen that Ru remains to a certain thickness even when the O₃ supply time is 180 seconds.

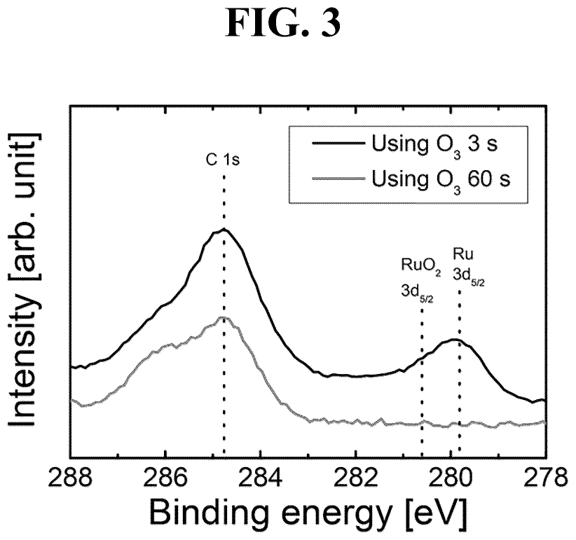

FIG. 3 is an XPS analysis result showing the presence or absence of residual Ru when the supply time of O₃ is applied as 3 seconds and 60 seconds, respectively, in a case where the deposition thickness of the Ru metal layer is 0.6 nm. With reference to FIG. 3, in the case where the O₃ supply time is 3 seconds, it can be confirmed that Ru is present, whereas in the case where the O₃ supply time is 60 seconds, Ru was not observed.

### Experimental Example 2: Crystal Structure of TiO₂

The crystal structure of TiO₂ deposited according to Experimental Example 1 was confirmed through XRD analysis.

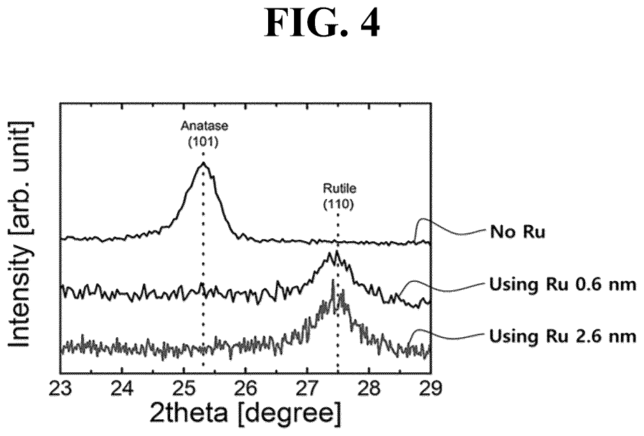

As a result of GIXRD analysis (see FIG. 4) of the deposited TiO₂ in the cases where the Ru metal layer was applied with deposition thicknesses of 0.6 nm and 2.5 nm, respectively, it can be confirmed that TiO₂ having a rutile crystal structure was formed in both cases. On the other hand, in the case of TiO₂ deposited without the Ru metal layer, it can be confirmed that TiO₂ having an anatase crystal structure was formed.

### Experimental Example 3: Dielectric Characteristics 1 of Capacitor

A capacitor was manufactured in order to verify the permittivity. In the case where the 0.6 nm Ru metal layer was applied in Experimental Example 1, an upper electrode of RuO₂ was further laminated on the rutile TiO₂ to complete the capacitor. In addition, capacitors having rutile TiO₂ with different thicknesses were manufactured in order to measure the dielectric constant. Here, the Al₂O₃ provided between the Si substrate (n⁺⁺) and the rutile TiO₂ corresponds to a lower dielectric layer for blocking leakage current of the capacitor.

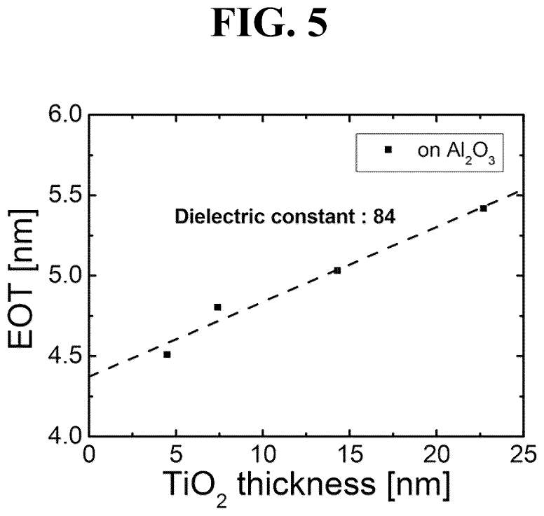

FIG. 5 shows a change in equivalent oxide film thickness according to the thickness of rutile TiO₂, and with reference to FIG. 5, it can be seen that the dielectric constant of rutile TiO₂ is about 84 from the slope of the change in equivalent oxide film thickness according to the thickness of rutile TiO₂. As is known, the dielectric constant of rutile TiO₂ is about 80, and the result of FIG. 5 can be said to be a counterevidence that the TiO₂ manufactured according to the present invention has a rutile crystal structure.

### Experimental Example 4: Dielectric Characteristics 2 of Capacitor

A capacitor was manufactured by applying different materials for the electrodes and the lower dielectric layer of the capacitor, and the crystal structure and dielectric characteristics of the TiO₂ deposited as in Experimental Examples 2 and 3 were confirmed.

While applying the same process conditions as in Experimental Example 3 to manufacture the capacitor, TiN was applied instead of the Si substrate (n⁺⁺) , and HfO₂ (3 nm) and ZrO₂ (3 nm) were applied instead of Al₂O₃ as the lower dielectric layer. The upper electrode was applied as RuO₂, the same as in Experimental Example 3.

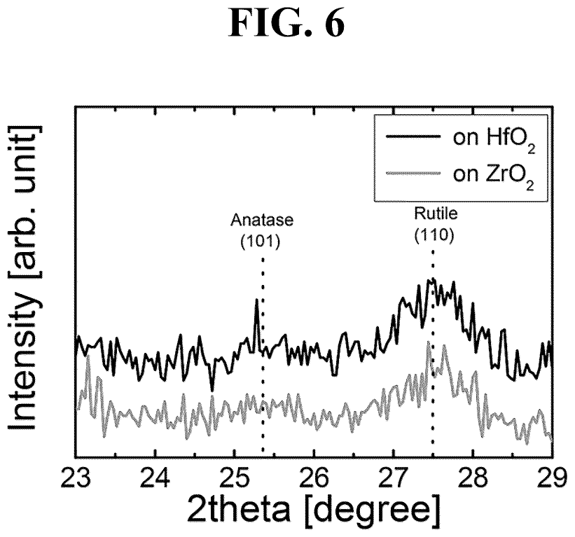

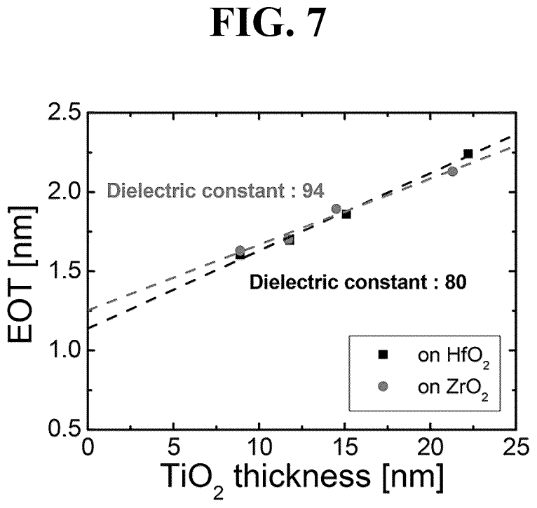

With reference to FIG. 6, it can be confirmed that even in the case where HfO₂ and ZrO₂ were applied, the deposited TiO₂ forms a rutile crystal structure. In addition, with reference to FIG. 7, it was confirmed that the dielectric constant of rutile TiO₂ is about 80 in the case where HfO₂ was applied, and the dielectric constant of rutile TiO₂ is about 94 in the case where ZrO₂ was applied.

What is claimed is:

1. A layered structure of a TiO₂ thin film having a rutile crystal structure, comprising:
a substrate; and
a rutile TiO₂ thin film laminated on the substrate,
wherein a crystal structure of the substrate and a crystal structure of the rutile TiO₂ thin film are different from each other, and the rutile TiO₂ thin film is formed by an atomic layer deposition (ALD) process at 400 ° C. or less.

2. The layered structure of claim 1, wherein the substrate is one of a semiconductor substrate, a conductive substrate, or an insulating substrate.

3. The layered structure of claim 1, wherein the substrate is a lower electrode of a capacitor or has a structure in which an insulating layer is provided on the lower electrode.

4. The layered structure of claim 3, wherein the lower electrode of the capacitor is made of one of TiN, TiAlN, Si, NbN, TaN, or MoN, and the insulating layer is made of one of ZrO₂, HfO₂, Al₂O₂, LaOₓ, TaOₓ, or NbOₓ.

5. The layered structure of claim 3, wherein an upper electrode of the capacitor is further provided on the rutile TiO₂ thin film.

6. A method for forming a TiO₂ thin film having a rutile crystal structure, comprising:
a first step of laminating an ultra-thin film sacrificial layer on a substrate; and
a second step of depositing a rutile TiO₂ thin film on the substrate through an atomic layer deposition (ALD) process,
wherein,
in the second step,
a reaction in which the rutile TiO₂ thin film is formed on the ultra-thin film sacrificial layer in the form of a metal oxide having structural consistency with rutile TiO₂, and a reaction in which the ultra-thin film sacrificial layer in the form of the metal oxide reacts with an oxidizing agent to be converted into a volatile oxide and removed, are carried out.

7. The method of claim 6, wherein the ultra-thin film sacrificial layer is capable of existing as a metal oxide having structural consistency with rutile TiO₂ and is capable of being converted into a volatile oxide, which is a gaseous material, when reacting with an oxidizing agent.

8. The method of claim 6, wherein a crystal structure of the substrate and a crystal structure of the rutile TiO₂ thin film are different from each other.

9. The method of claim 6, wherein the ultra-thin film sacrificial layer is made of a metal or a metal oxide.

10. The method of claim 9, wherein the metal is one of Ru, Ir, Mo, V, Sn, or Nb, and the metal oxide is one of RuO₂, IrO₂, MoO₂, VO₂, SnO₂, or NbO₂.

11. The method of claim 6, wherein, when the ultra-thin film sacrificial layer is made of a metal,
in the second step,
a process in which the metal reacts with an oxidizing agent to be converted into a metal oxide having structural consistency with rutile TiO₂, a process in which the rutile TiO₂ thin film is formed on the metal oxide having structural consistency with rutile TiO₂, and a process in which the metal oxide having structural consistency with rutile TiO₂ reacts with the oxidizing agent to be converted into a volatile oxide and removed, are carried out.

12. The method of claim 6, wherein, when the ultra-thin film sacrificial layer is made of a metal oxide,
in the second step,
a process in which the rutile TiO₂ thin film is formed on the metal oxide having structural consistency with rutile TiO₂, and a process in which the metal oxide having structural consistency with rutile TiO₂ reacts with an oxidizing agent to be converted into a volatile oxide and removed, are carried out.

13. The method of claim 6, wherein the substrate is one of a semiconductor substrate, a conductive substrate, or an insulating substrate.

14. The method of claim 6, wherein the substrate is a lower electrode of a capacitor or has a structure in which an insulating layer is provided on the lower electrode.

15. The method of claim 14, wherein the lower electrode of the capacitor is made of one of TiN, TiAlN, Si, NbN, TaN, or MoN, and the insulating layer is made of one of ZrO₂, HfO₂, Al₂O₂, LaOₓ, TaOₓ, or NbOₓ.

16. The method of claim 6, wherein the ultra-thin film sacrificial layer has a thickness of 6 nm or less.

17. The method of claim 6, wherein the ultra-thin film sacrificial layer has a thickness of 3 nm or less.

18. The method of claim 6, wherein the ultra-thin film sacrificial layer has a thickness of 2.5 nm or less.

19. The method of claim 6, wherein the atomic layer deposition (ALD) process of the second step is carried out at a temperature of 400 °C or less.

20. The method of claim 6, wherein the atomic layer deposition (ALD) process of the second step comprises:
repeating a titanium precursor supply process and an oxidizing agent supply process, and
wherein the oxidizing agent is supplied by the oxidizing agent supply process, and the oxidizing agent is O₃ or O₂ plasma.
